(19) United States
(12) Patent Application Publication
(10) Pub. No.: US 2012/0268208 A1
(43) Pub. Date: Oct. 25, 2012

(54) SEMICONDUCTOR INTEGRATED CIRCUIT DEVICE

(75) Inventor: Tetsuro TAKENAKA, Miyazaki (JP)

(73) Assignee: LAPIS Semiconductor Co., Ltd., Tokyo (JP)

(21) Appl. No.: 13/452,811

(22) Filed: Apr. 20, 2012

(30) Foreign Application Priority Data
Apr. 21, 2011 (JP) 2011-094994

(51) Int. Cl. H03F 3/45

(52) U.S. Cl. 330/260

(57) ABSTRACT

There is provided a semiconductor integrated circuit device including: a differential amplification circuit having a non-inverting input terminal that receives a reference voltage and an inverting input terminal connected to an output load; and an output circuit including a first MOS transistor having a gate connected to an output terminal of the differential amplification circuit, a source, and a drain connected to the inverting input terminal of the differential amplification circuit such that the first MOS transistor is ON/OFF in an operation state/a non-operation state, and a second MOS transistor connected in series between a power source and the source of the first MOS transistor, with a gate width/gate length ratio of the second MOS transistor smaller than a gate width/gate length ratio of the first MOS transistor, such that the second MOS transistor is ON in the operation state and OFF in the non-operation state.

### CROSS-REFERENCE TO RELATED APPLICATION

This application is based on and claims priority under 35 USC 119 from Japanese Patent Application No. 2011-094994 filed on Apr. 21, 2011, the disclosure of which is incorporated by reference herein.

### BACKGROUND

1. Technical Field

The present invention is related to a semiconductor integrated circuit device.

2. Related Art

Various configurations of circuit are proposed for constant voltage generation circuits (regulators) (see for example Japanese Patent Application Laid-Open (JP-A) No. 2006-331235).

FIG. 6 shows a circuit diagram of an example of an existing regulator 100. As shown in FIG. 6, the regulator 100 is configured including an operational amplifier OP as a differential amplification circuit and an output circuit X10.

The operational amplifier OP, as shown in FIG. 7, is a differential amplification circuit configured including PMOS transistors p00, p01 and NMOS transistors n00, n01, n02. In the operational amplifier OP the PMOS transistor p00 and the NMOS transistor n00 are connected together in series, and the PMOS transistor p01 and the NMOS transistor n01 are connected together in series. The sources of the PMOS transistors p00, p01 are connected to a power source vdd, and the sources of the NMOS transistors n00, n01 are connected to the drain of the NMOS transistor n02. The source of the NMOS transistor n02 is grounded.

The gate of the NMOS transistor n00 is connected to an inverting input terminal, the gate of the NMOS transistor n01 is connected to a non-inverting input terminal, and the gate of the NMOS transistor n02 is input with a bias voltage signal vb. The connection point of the drain of the PMOS transistor p01 and the drain of the NMOS transistor n01 configures the output terminal o/ of the operational amplifier OP.

The output circuit X10, as shown in FIG. 6, is configured including PMOS transistors p10, p11 and an NMOS transistor n11.

The source of the PMOS transistor p10 is connected to power source vdd, the gate of the PMOS transistor p10 is input with an activation signal act, and the drain of the PMOS transistor p10 is connected to the output terminal o/ of the operational amplifier OP and the gate of the PMOS transistor p11.

The source of the PMOS transistor p11 is connected to the power source vdd, the gate of the PMOS transistor p11 is connected to the output terminal o/ of the operational amplifier OP and the drain of the PMOS transistor p10, and the drain of the PMOS transistor p11 is connected to the inverting input terminal of the operational amplifier OP and the drain of the NMOS transistor n11.

The drain of the NMOS transistor n11 is connected to the inverting input terminal of the operational amplifier OP and the drain of the PMOS transistor p11, the gate of the NMOS transistor n11 is input with the bias voltage signal vb, and the source of the NMOS transistor n11 is grounded.

The non-inverting input terminal of the operational amplifier OP is input with a reference voltage signal ref. The inverting input terminal of the operational amplifier OP is connected to the drains of the PMOS transistor p11 and the NMOS transistor n11, with this connection point configuring an output terminal xout of the regulator 100 that is connected to an output load 106.

An output load Y is operated by supply of voltage ivc10 output from the output terminal xout of the regulator 100. For simplicity of explanation, the output load Y in FIG. 6 is illustrated by being replaced with a current source D in which current iL flows.

Explanation follows regarding operation of the regulator 100, with reference to the timing chart illustrated in FIG. 8.

As shown in FIG. 8, when the activation signal act is low level the regulator 100 is in a non-operation state, and when the activation signal act is high level the regulator 100 is in an operation state.

The reference voltage signal ref and the bias voltage signal vb are signals synchronized with the activation signal act, as shown in FIG. 8.

When the activation signal act is high level, namely when the regulator 100 is in an operation state, as shown in FIG. 8, the output voltage ivc10 of the regulator 100 is an intermediate level voltage substantially the same as the reference voltage signal ref. However, when the activation signal act is low level, namely when the regulator 100 is in a non-operation state, even though the PMOS transistor p11 is high impedance due to being cut off, the output voltage ivc10 ultimately reaches ground level due to the output load Y.

A current iL flowing in the output load Y when the regulator 100 is in the operation state is an operation current of for internal circuits configuring the output load Y employing the output voltage ivc10 as the power source. However, when the regulator 100 in the non-operation state the current iL is an off-leakage current of the internal circuits. Note that, for example, the current iL in the operation state is several mA and the current iL in the non-operation state is 1 μA or less.

However, along with recent increases in current iL of the output load Y such as for applications applicable to self-writing of flash memory and applicable to capless regulators, sometimes it is desirable to increase the drive power of the PMOS transistor p11 of the output circuit X10 of the regulator 100. In such cases there is a specific need to increase the dimensions of the PMOS transistor p11, namely to increase the gate width/gate length ratio.

As the gate width/gate length ratio increases, the off-leakage current of the PMOS transistor p11 in the non-operation state exceeds the current iL flowing in the internal circuits of the output load Y, and as shown in FIG. 9, the output voltage ivc10 rises to the level of power source vdd. This occurs since, in contrast to the increase in the off-leakage current of the PMOS transistor p11 due to increasing the drive power of the PMOS transistor p11, there is relatively little change in the off-leakage current of the internal circuits of the output load Y, so the off-leakage current of the PMOS transistor p11 exceeds the off-leakage current of the internal circuits of the output load Y, and the PMOS transistor p11 is ON in a low current state.

Therefore, as shown in FIG. 9, there is a concern of violating the voltage withstanding ability and causing malfunction of transistors, not shown in the drawings, configuring the internal circuits of the output load Y employing the output voltage ivc10 of the regulator 100 as a power source.

### SUMMARY

In consideration of the above circumstances an object of the present invention is to provide a semiconductor integrated circuit device that, even when the drive power of transistors configuring a circuit for outputting a constant voltage is raised, is capable of preventing the off-leakage current of these transistors exceeding the off-leakage current of an output load employing the constant voltage as a power source.

In order to achieve the above object, the present invention provides a semiconductor integrated circuit device including:

a differential amplification circuit having a non-inverting input terminal and an inverting input terminal, the non-inverting input terminal being input with a reference voltage and the inverting input terminal being connected to an output load; and

an output circuit including a first MOS transistor having a gate connected to an output terminal of the differential amplification circuit, a source, and a drain connected to the inverting input terminal of the differential amplification circuit such that the first MOS transistor is ON in an operation state and OFF in a non-operation state, and a second MOS transistor connected in series between a power source and the source of the first MOS transistor, with a gate width/gate length ratio of the second MOS transistor smaller than a gate width/gate length ratio of the first MOS transistor, such that the second MOS transistor is ON in the operation state and OFF in the non-operation state.

According to the present invention, the advantageous effect is exhibited of being able to prevent the off-leakage current of transistors configuring a circuit for outputting a constant voltage exceeding the off-leakage current of an output load employing the constant voltage as a power source even when the drive power of these transistors is raised.

### BRIEF DESCRIPTION OF THE DRAWINGS

Exemplary embodiments of the present invention will be described in detail based on the following figures, wherein:

FIG. 1 is a circuit diagram of a regulator according to a first exemplary embodiment;

FIG. 2 is a timing chart illustrating signals in each section of a regulator according to the first exemplary embodiment;

FIG. 3 is a circuit diagram of a regulator according to a second exemplary embodiment;

FIG. 4 is a circuit diagram of an operational amplifier according to the second exemplary embodiment;

FIG. 5 is a timing chart illustrating signals of each section of a regulator according to the second exemplary embodiment;

FIG. 6 is a circuit diagram of a regulator according to a related art;

FIG. 7 is a circuit diagram of an operational amplifier according to the related art;

FIG. 8 is a timing chart illustrating signals of each section of a regulator according to the related art; and

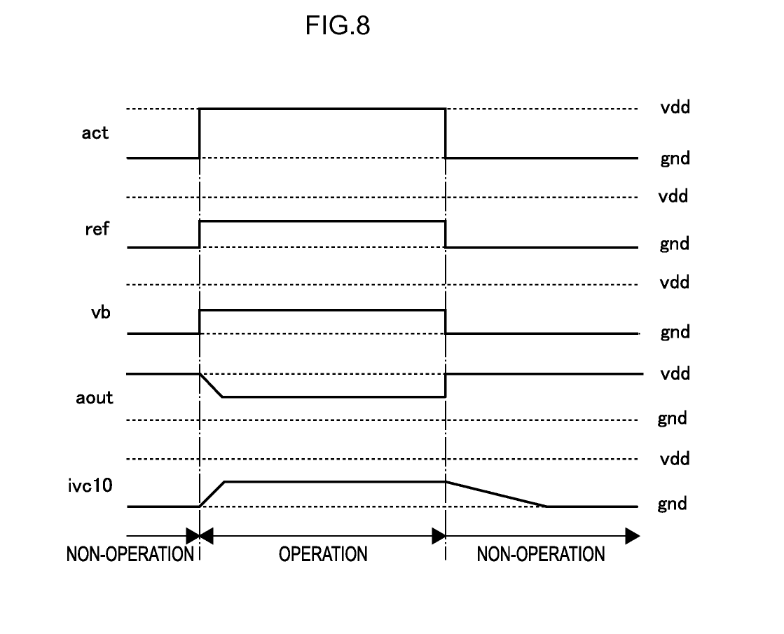

FIG. 9 is a timing chart illustrating signals of each section of a regulator according to the related art.

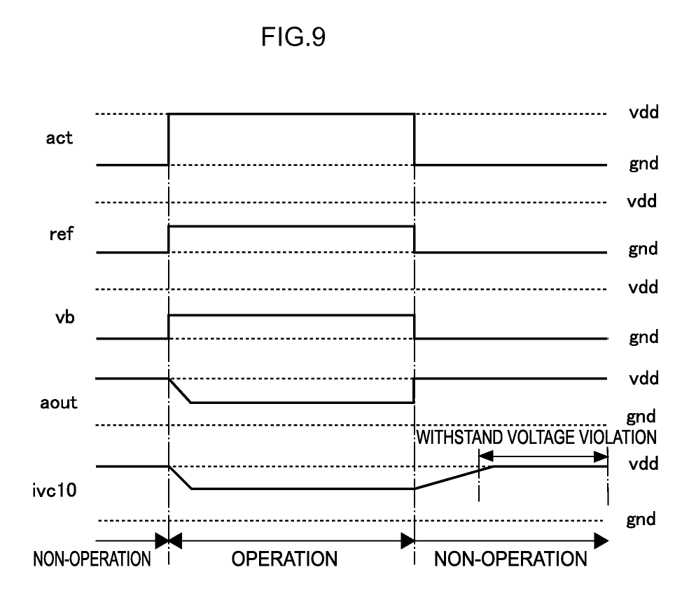

### DETAILED DESCRIPTION

Detailed explanation follows regarding preferable exemplary embodiments of the present invention, with reference to the drawings.

### First Exemplary Embodiment

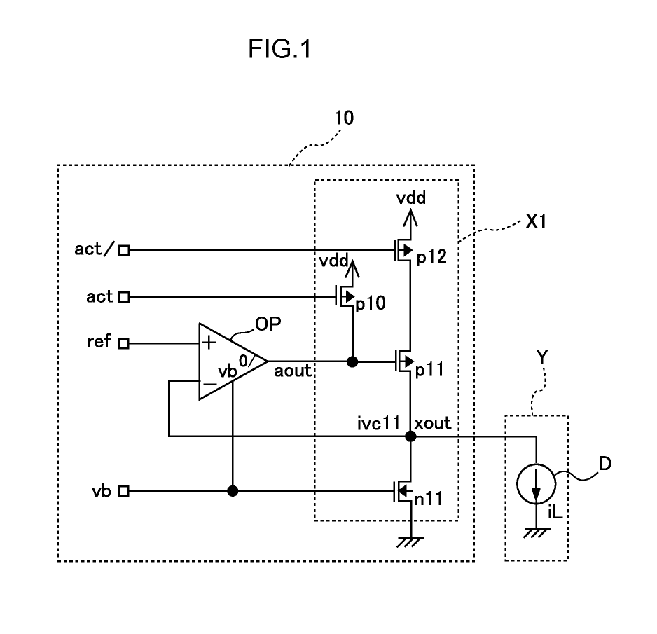

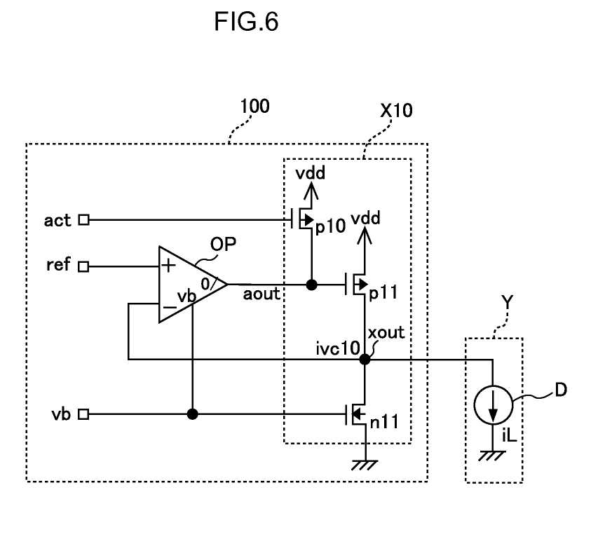

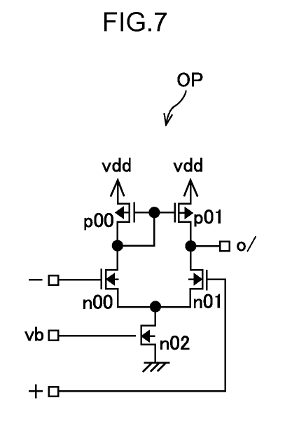

FIG. 1 is a circuit configuration diagram illustrating a regulator 10 according to a first exemplary embodiment of the present invention. Similar portions to those of FIG. 6 are appended with the same reference numerals. As shown in FIG. 1, the regulator 10 is configured including an operational amplifier OP serving as a differential amplification circuit and an output circuit X1. Since the operational amplifier OP is similar to that of the configuration illustrated in the already described FIG. 7, further explanation is omitted.

The output circuit X1, as shown in FIG. 1, is configured including PMOS transistors p10, p11 (first MOS transistors), a PMOS transistor p12 (second MOS transistor), and an NMOS transistor n11. The output circuit X1 accordingly differs from the output circuit X10 illustrated in FIG. 6 in the provision of the PMOS transistor p12.

The source of the PMOS transistor p10 is connected to the power source vdd, the gate of the PMOS transistor p10 is input with an activation signal act, and the drain of the PMOS transistor p10 is connected to the output terminal o/ of the operational amplifier OP and the gate of the PMOS transistor p11.

The source of the PMOS transistor p11 is connected to the drain of the PMOS transistor p12, the gate of the PMOS transistor p11 is connected to the output terminal o/ of the operational amplifier OP and the drain of the PMOS transistor p10, and the drain of the PMOS transistor p11 is connected to the inverting input terminal of the operational amplifier OP and the drain of the NMOS transistor n11.

The drain of the PMOS transistor p12 is connected to the power source vdd, the gate of the PMOS transistor p12 is input with an inverted activation signal act/ that is the inversion of activation signal act, and the drain of the PMOS transistor p12 is connected to the source of the PMOS transistor p11.

The drain of the NMOS transistor n11 is connected to the inverting input terminal of the operational amplifier OP and the drain of the PMOS transistor p11, the gate of the NMOS transistor n11 is input with a bias voltage signal vb, and the source of the NMOS transistor n11 is grounded.

A reference voltage signal ref is input to the non-inverting input terminal of the operational amplifier OP. The inverting input terminal of the operational amplifier OP is connected to the drains of the PMOS transistor p11 and the NMOS transistor n11, and this connection point serves as output terminal xout of the regulator 10, and is connected to an output load Y.

The output load Y is operated by supply of a voltage ivc11 output from the output terminal xout of the regulator 10. In order to simplify explanation the output load Y is replaced in FIG. 1 by a current source D in which a current iL flows.

The dimensions of the PMOS transistor p12, namely the gate width/gate length ratio are set such that the off-leakage current of the PMOS transistor p12 is smaller than the current iL flowing in the output load Y in the non-operation state, namely smaller than the off-leakage current of the internal circuits of the output load Y employing the output voltage ivc11 as the power source. The off-leakage current of the internal circuits of the output load Y can be predetermined by the configuration of these internal circuits. Consequently, the gate width/gate length ratio of the PMOS transistor p12 is determined in order to make the off-leakage current of the PMOS transistor p12 less than the predetermined off-leakage current of the internal circuits of the output load Y.

The gate width/gate length ratio of the PMOS transistor p11 is a gate width/gate length ratio corresponding to the drive power required. Configuration of the gate width/gate length ratio of the PMOS transistor p12 may be made such that, for example, the gate width thereof is made smaller than the gate width of the PMOS transistor p11 such that the gate width/gate length ratio is smaller than the gate width/gate length ratio of the PMOS transistor p11, and/or the gate length thereof may be made longer than the gate length of the PMOS transistor p11 such that the gate width/gate length ratio is smaller than the gate width/gate length ratio of the PMOS transistor p11. However, preferably only the gate width is decreased since the size of the PMOS transistor p12 can be decreased, and the circuit surface area can be reduced.

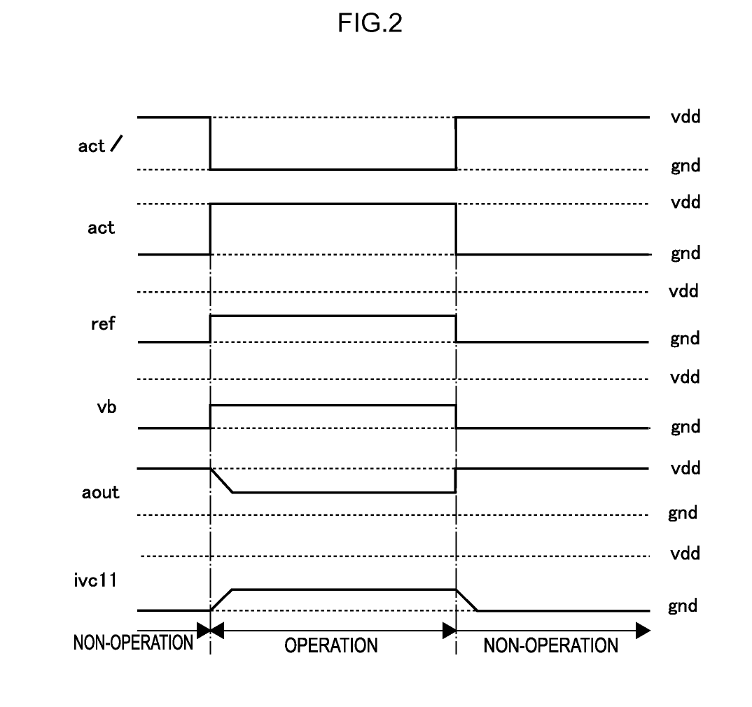

Explanation follows regarding operation of the regulator 10, with reference to the timing chart illustrated in FIG. 2.

As shown in FIG. 2, when the activation signal act is low level the regulator 10 is in a non-operation state, and when the activation signal act is high level the regulator 10 is in an operation state.

The reference voltage signal ref and the bias voltage signal vb are, as shown in FIG. 2, signals synchronized to the activation signal act.

When the activation signal act is high level, namely when the regulator 10 is in an operation state, the PMOS transistor p11 is in a saturated region and in an ON state due to application of the output voltage aout of the operational amplifier OP. On the other hand, since the inverted activation signal act/ is low level the PMOS transistor p12 is in a non-saturated region and in an ON state. The output voltage ivc11 is accordingly, as shown in FIG. 2, an intermediate level voltage substantially the same as the reference voltage signal ref.

However, when the activation signal act is low level, namely when the regulator 10 is in a non-operation state, the PMOS transistor p10 turns ON, the output voltage aout of the operational amplifier OP becomes high level, and PMOS transistor p11 is cut off. Since the inverted activation signal act/ becomes high level the PMOS transistor p12 is also cut off, and the output voltage ivc11 is high impedance.

As described above, the dimensions of the PMOS transistor p12, namely the gate width/gate length ratio, are set such that the off-leakage current of the PMOS transistor p12 is smaller than the current iL flowing in the output load Y in the non-operation state, namely smaller than the off-leakage current of the internal circuits of the output load Y employing the output current ivc20 as a power source. The output voltage ivc11 accordingly ultimately reaches ground level, as shown in FIG. 2.

The off-leakage current flowing in to the output voltage ivc11 of the regulator 10 from the power source vdd is determined by the dimensions of the PMOS transistor p12, and the off-leakage current flowing out to ground from the output voltage ivc11 of the regulator 10 is determined by the off-leakage current of the internal circuits of the output load Y employing the output voltage of the output voltage ivc11 as a power source.

Therefore, the output voltage of the output voltage ivc20 can be prevented from rising to the level of the power source vdd in the non-operation state by setting the dimensions of the PMOS transistor p12, namely the gate width/gate length ratio, such that the off-leakage current of the PMOS transistor p12 is smaller than the off-leakage current of the internal circuits of the output load Y employing the output voltage ivc11 as a power source.

In the operation state of the regulator 10, the current supply power of the output circuit X1 is dependent on the PMOS transistor p11 since the PMOS transistor p12 is in an ON state, and the ON resistance of the PMOS transistor p12 can be ignored.

Explanation has been given of cases in the present exemplary embodiment in which the PMOS transistors p11, p12 are both configured by the same type of PMOS transistor, however configuration may be made for example with the PMOS transistor p11 configured by a low Vt element. Namely, the PMOS transistor p11 may be configured by a low Vt element with a lower threshold voltage than that of the PMOS transistor p12 and through which a lot of current can be made to flow. The size of the PMOS transistor p12 can accordingly be decreased, and the circuit surface area can be decreased.

### Second Exemplary Embodiment

Explanation follows regarding a second exemplary embodiment of the present invention. Portions similar to those of the first exemplary embodiment are appended with the same reference numerals and further detailed explanation is omitted.

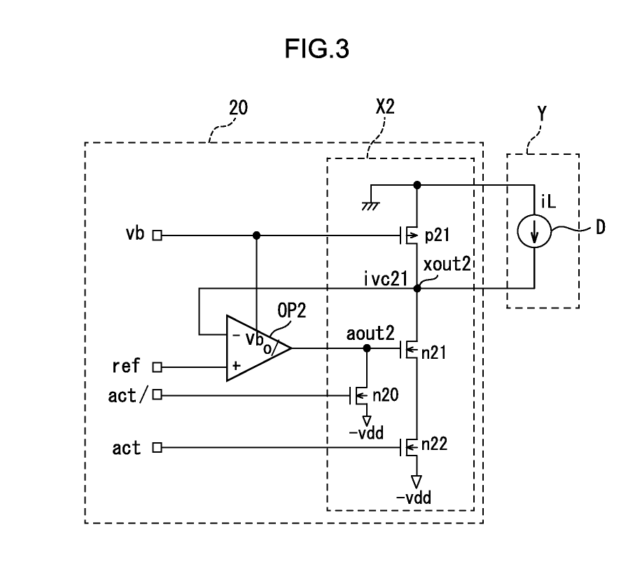

FIG. 3 is a circuit configuration diagram illustrating a regulator 20 according to the second exemplary embodiment of the present invention. Portions similar to those of FIG. 1 are appended with the same reference numerals. As shown in FIG. 3, the regulator 20 is configured including an operational amplifier OP2 serving as a differential amplification circuit and an output circuit X2.

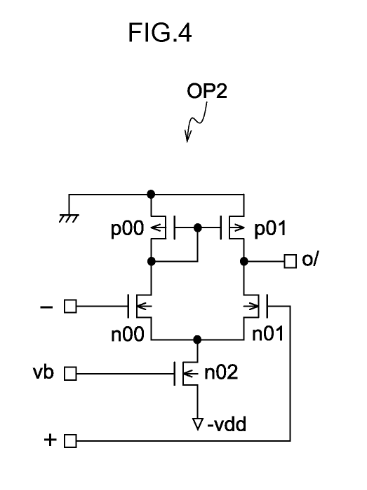

As shown in FIG. 4, in the operational amplifier OP2, PMOS transistors p00, p01 and NMOS transistors n00, n01, n02 are connected together as illustrated in FIG. 4 so as to configure a differential amplification circuit.

The operational amplifier OP2 is, similarly to the operational amplifier OP illustrated in FIG. 7, a differential amplification circuit configured including the PMOS transistors p00, p01 and the NMOS transistors n00, n01, n02, however it differs therefrom in that the sources of the PMOS transistors p00, p01 are grounded, and the source of the NMOS transistor n02 is connected to a minus power source −vdd.

The output circuit X2 according to the present exemplary embodiment is configured with the following replacements made to the output circuit X1 explained in the first exemplary embodiment: the PMOS transistor p10 is replaced by an NMOS transistor n20; the PMOS transistor p11 is replaced by an NMOS transistor n21 (first MOS transistor); the PMOS transistor p12 is replaced by an NMOS transistor n22 (second MOS transistor); and the NMOS transistor n11 is replaced by a PMOS transistor p21.

The source of the NMOS transistor n20 is connected to the minus power source −vdd, the gate of the NMOS transistor n20 is input with inverted activation signal act/ that is the inversion of activation signal act, and the drain of the NMOS transistor n20 is connected to the output terminal o/ of the operational amplifier OP2 and the gate of the NMOS transistor n21.

The source of the NMOS transistor n21 is connected to the drain of the NMOS transistor n22, the gate of the NMOS transistor n21 is connected to the output terminal o/ of the operational amplifier OP2 and the drain of the NMOS transistor n20, and the drain of the NMOS transistor n21 is connected to the inverting input terminal of the operational amplifier OP2 and the drain of the PMOS transistor p21.

The source of the NMOS transistor n22 is connected to the minus power source −vdd, the gate of the NMOS transistor n22 is input with the activation signal act, and the drain of the NMOS transistor n22 is connected to the source of the NMOS transistor n21.

The drain of the PMOS transistor p21 is connected to the inverting input terminal of the operational amplifier OP2 and the drain of the NMOS transistor n21, the gate of the PMOS transistor p21 is input with bias voltage signal vb, and the source of the PMOS transistor p21 is connected to the output load Y and also grounded.

The reference voltage signal ref is input to the non-inverting input terminal of the operational amplifier OP2. The inverting input terminal of the operational amplifier OP2 is connected to the PMOS transistor p21 and the drain of the NMOS transistor n21, and this connection point configures output terminal xout2 of the regulator 20 and is connected to the output load Y.

The output load Y is operated by supplying voltage ivc21 output from output terminal xout2 of the regulator 20. In order to simplify explanation, the output load Y is replaced in FIG. 3 by a current source D in which current iL flows.

In the thus configured regulator 20, similarly to in the first exemplary embodiment, the dimension of the NMOS transistor n22, namely the gate width/gate length ratio, is also set such that the off-leakage current of the NMOS transistor n22 is smaller than the current iL flowing in the output load Y in a non-operation state, namely smaller than the off-leakage current of the internal circuits of the output load Y employing the voltage ivc21 as a power source. The off-leakage current of the internal circuits of the output load Y can be predetermined by the configuration of the internal circuits. Consequently, the gate width/gate length ratio of the NMOS transistor n22 is determined such that the off-leakage current of the NMOS transistor n22 is smaller than the predetermined off-leakage current of the internal circuits of the output load Y.

The gate width/gate length ratio of the NMOS transistor n21 is a gate width/gate length ratio corresponding to the required drive power. The gate width/gate length ratio of the NMOS transistor n22 may be set for example with a smaller gate width than the gate width of the NMOS transistor n21 such that the gate width/gate length ratio is smaller than the gate width/gate length ratio of the NMOS transistor n21, or with a longer gate length than the gate length of the NMOS transistor n21, such that the gate width/gate length ratio is smaller than the gate width/gate length ratio of the NMOS transistor n21. However, preferably only the gate width is decreased since the size of the NMOS transistor n22 can be decreased and the circuit surface area can be reduced.

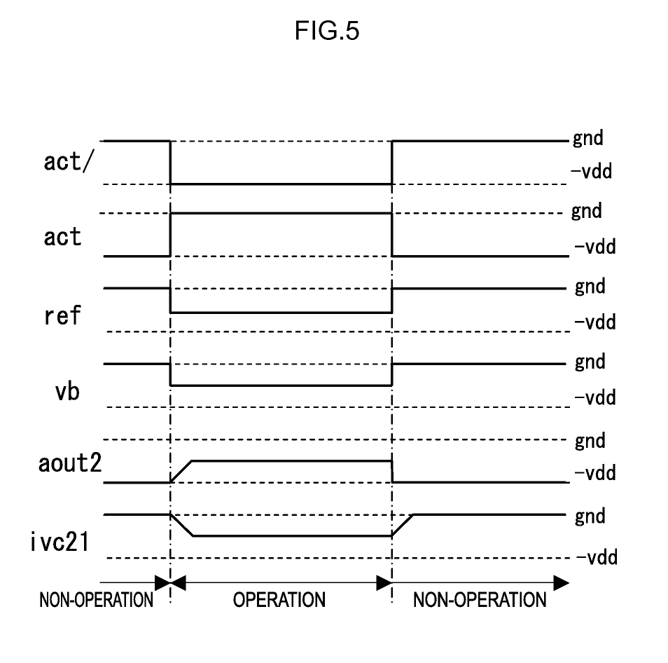

Explanation follows regarding operation of the regulator 20, with reference to the timing chart illustrated in FIG. 5.

As shown in FIG. 5, when the activation signal act is low level the regulator 20 is in a non-operation state and when the activation signal act is high level the regulator 20 is in an operation state.

The reference voltage signal ref and the bias voltage signal vb are, as shown in FIG. 5, signals synchronized to the activation signal act.

When the inverted activation signal act/ is low level (the activation signal act is high level), namely when the regulator 20 is in an operation state, the NMOS transistor n21 is in a saturated region and in an ON state due the output voltage aout2 of the operational amplifier OP2. On the other hand, since the activation signal act is high level the NMOS transistor n22 is in a non-saturated region and in an ON state. The output voltage ivc21 is, as shown in FIG. 5, accordingly a voltage of intermediate level substantially the same as the reference voltage signal ref.

When the inverted activation signal act/ is high level (the activation signal act is low level), namely when the regulator 20 is in a non-operation state, the NMOS transistor n20 turns ON, and the output voltage aout2 of the operational amplifier OP2 becomes low level, and the NMOS transistor n21 is cut off, and since the NMOS transistor n22 is also cut off with the activation signal act at low level, the output voltage ivc21 has high impedance.

As described above, the dimensions of the NMOS transistor n22, namely the gate width/gate length ratio, have been set such that off-leakage current of the NMOS transistor n22 is smaller than the current iL flowing in the output load Y in the non-operation state, namely the off-leakage current of the internal circuits of the output load Y employing the output voltage ivc21 as the power source. The output voltage ivc21 accordingly ultimately reaches ground level, as shown in FIG. 5.

The off-leakage current flowing into the output voltage ivc21 of the regulator 20 from ground is determined by the dimensions of the NMOS transistor n22, and the off-leakage current flowing out from the output voltage ivc21 of the regulator 20 to the minus power source −vdd is determined by the off-leakage current of the internal circuits of the output load Y employing the output voltage ivc21 as the power source.

Since the dimensions of the NMOS transistor n22, namely the gate width/gate length ratio, have been set such that the off-leakage current of the NMOS transistor n22 is smaller than the off-leakage current of the internal circuits of the output load Y employing the output voltage ivc21 as the power source, the output voltage of the output voltage ivc21 can be prevented from falling to the level of minus power source −vdd in a non-operation state.

Note that while in each of the above exemplary embodiments examples have been given of application of the present invention to a regulator, there is no limitation thereto. The present invention may be applied, for example, to a bias circuit for generating a reference voltage.

What is claimed is:

1. A semiconductor integrated circuit device comprising:
a differential amplification circuit having a non-inverting input terminal and an inverting input terminal, the non-inverting input terminal being input with a reference voltage and the inverting input terminal being connected to an output load; and
an output circuit comprising a first MOS transistor having a gate connected to an output terminal of the differential amplification circuit, a source, and a drain connected to the inverting input terminal of the differential amplification circuit such that the first MOS transistor is ON in an operation state and OFF in a non-operation state, and a second MOS transistor connected in series between a power source and the source of the first MOS transistor, with a gate width/gate length ratio of the second MOS transistor smaller than a gate width/gate length ratio of the first MOS transistor, such that the second MOS transistor is ON in the operation state and OFF in the non-operation state.

2. The semiconductor integrated circuit device of claim 1, wherein the gate width of the second MOS transistor is smaller than the gate width of the first MOS transistor.

3. The semiconductor integrated circuit device of claim 1, wherein a threshold voltage of the first MOS transistor is lower than a threshold voltage of the second MOS transistor.

4. The semiconductor integrated circuit device of claim 1, wherein
the first MOS transistor and the second MOS transistor are PMOS transistors, and
the power source is a power source that outputs a positive voltage.

5. The semiconductor integrated circuit device of claim 1, wherein
the first MOS transistor and the second MOS transistor are NMOS transistors, and
the power source is a power source that outputs a negative voltage.
